(19) United States
(12) Patent Application Publication
(10) Pub. No.: US 2012/0306047 A1
(43) Pub. Date: Dec. 6, 2012

(54) CHIP-ON-FILM STRUCTURE FOR LIQUID CRYSTAL PANEL

(75) Inventors: Liangchan Liao, Shenzhen (CN); Poshen Lin, Shenzhen (CN); Yu Wu, Shenzhen (CN)

(73) Assignee: Shenzhen China Star Optoelectronics Technology Co. Ltd., Shenzhen (CN)

(21) Appl. No.: 13/264,856

(22) PCT Filed: Jul. 11, 2011
(86) PCT No.: PCT/CN2011/077043

§ 371 Date: Oct. 17, 2011

(30) Foreign Application Priority Data
Jun. 6, 2011 (CN) 201120187053.0

(51) Int. Cl. H01L 29/02

(52) U.S. Cl. 257/506; 257/E29.002

(57) ABSTRACT

The present invention provides a chip on film (COF) structure for a liquid crystal panel, which is disposed on an edge of a glass substrate of an array substrate of a liquid crystal panel. The COF structure comprises a plastic substrate, a metal layer, an adhesive layer, a driver chip and an insulating protection layer. The COF structures further comprises at least one groove, and the groove is disposed on the plastic substrate over the output terminals of the metal layer. The at least one groove of the present invention can prevent from deformation and damage of the glass substrate when the COF structure is assembled with the glass substrate of the array substrate, and it can reduce the brightness difference of the glass substrate in the thermally pressed regions.

### FIELD OF THE INVENTION

The present invention relates to a chip-on-film (COF) structure for a liquid crystal panel, and more particularly to a COF structure which can reduce the deformation of an array substrate generated when the COF structure is thermally pressed onto the liquid crystal panel.

### BACKGROUND OF THE INVENTION

A liquid crystal display (LCD) is a type of flat panel display (FPD) which displays images by the property of the liquid crystal material. In comparison with other display devices, the LCD has the advantages in lightweight, compactness, low driving voltage and low power consumption, and thus has already become the mainstream product in the whole consumer market.

In a traditional process of LCD panel, it comprises a front-end array process, a mid-end cell process and a back-end modulation process. The front-end array process is used to produce thin-film transistor (TFT) substrates (also called array substrates) and color filter (CF) substrates; the mid-end cell process is used to combine the TFT substrate with the CF substrate, then fill liquid crystal into a space therebetween, and cut to form panels with a suitable product size; and the back-end modulation process is used to execute an installation process of the combined panel, a backlight module, a panel driver circuit, an outer frame, etc.

As mentioned above, an assembly of driver ICs of the back-end modulation process is an assembling technology to combine the packaged driver ICs with the LCD panel. There are various packaging types of the driver IC for LCD, such as quad flat package (QFP), chip on glass (COG), tape automated bonding (TAB), chip on film (COF), etc, wherein the COF structure has flexibility and smaller circuit pitches, so as to become the main technology of the package of driver ICs.

Referring now to FIGS. 1 and 2, a top view of a traditional COF structure assembled on a liquid crystal panel is illustrated in FIG. 1, and a cross-sectional side view of the traditional COF structure assembled on the liquid crystal panel is illustrated in FIG. 2, wherein a liquid crystal panel 91 has a color filter (CF) substrate 911 and a glass substrate 912 of an array substrate, and an edge of the glass substrate 912 is provided with a chip on film (COF) structure 92. The COF structure 92 comprises: a plastic substrate 921, a metal layer 922, an adhesive layer 923, a driver chip 924 and an insulating protection layer 925. The plastic substrate 921 is a plastic substrate with flexibility; two ends of the metal layer 922 is provided with a plurality of input terminals 922a and a plurality of output terminals 922b, respectively; the adhesive layer 923 is disposed between the plastic substrate 921 and the metal layer 922 for bonding the plastic substrate 921 with the metal layer 922; the driver chip 924 is disposed on the outer surface of the plastic substrate 921, and electrically connected with the metal layer 922 (not shown); the Insulating protection layer 925 is disposed on the outer surface of the metal layer 922, and exposes the input terminals 922a and the output terminals 922b.

As shown in FIGS. 1 and 2, when the COF structure 92 is assembled with the glass substrate 912 of the array substrate, an anisotropic conductive film (ACF) 930 is provided between the output terminals 922b of the COF structure 92 and a plurality of terminals (not shown) on an edge of the glass substrate 912, and the output terminals 922b will be electrically connected with the terminals of the glass substrate 912 by heating and pressing (referring to the direction of the arrow as shown in FIG. 2) the plastic substrate 921 over the output terminals 922b, so as to finish the assembly of the COF structure 92 and the liquid crystal panel 91.

However, there is a question existing in the mentioned assembly, i.e. because the glass substrate 912 of the array substrate needs to be installed with a plurality of the COF structures 92, and the COF structures 92 are disposed on the glass substrate 912 by thermally pressing, it causes that the glass at thermally pressed regions becomes deformed and warped, so that a gap between the upper CF substrate 911 and the lower glass substrate 912 of the array substrate has a variation between the thermally pressed regions and non-thermally pressed regions thereof, and thus it causes the transmittance of light has a variation between different regions.

As a result, it is necessary to provide a COF structure for a liquid crystal panel to solve the problems existing in the conventional technologies.

### SUMMARY OF THE INVENTION

The present invention provides a chip on film (COF) structure for a liquid crystal panel, so as to solve the problem existing in the conventional technologies that a gap of two glass substrates has a variation.

To achieve the above object, the present invention provides a COF structure for a liquid crystal panel, which is disposed on an edge of a glass substrate of an array substrate of a liquid crystal panel, the COF structure comprises:

a plastic substrate being a plastic substrate of polyimide (PI);

a metal layer having two ends provided with a plurality of input terminals and a plurality of output terminals, respectively;

an adhesive layer disposed between the plastic substrate and the metal layer to bond the plastic substrate with the metal layer;

a driver chip disposed on the outer surface of the plastic substrate, and being electrically connected with the metal layer; and

an insulating protection layer disposed on the outer surface of the metal layer, and exposing the input terminals and the output terminals;

wherein the COF structure further comprises:

at least one sawtooth-like groove disposed over the output terminals of the metal layer, wherein when the COF structure is assembled with the glass substrate of the array substrate, an anisotropic conductive film (ACF) is provided between the output terminals of the COF structure and a plurality of terminals of the glass substrate, and the output terminals are electrically connected to the terminals of the glass substrate by heating and pressing the plastic substrate over the output terminals.

To achieve the above object, the present invention further provides a COF structure for a liquid crystal panel, which is disposed on an edge of a glass substrate of an array substrate of a liquid crystal panel, the COF structure comprises:

a plastic substrate;

a metal layer having two ends provided with a plurality of input terminals and a plurality of output terminals, respectively;

an adhesive layer disposed between the plastic substrate and the metal layer to bond the plastic substrate with the metal layer;

a driver chip disposed on the outer surface of the plastic substrate, and being electrically connected with the metal layer; and an insulating protection layer disposed on the outer surface of the metal layer, and exposing the input terminals and the output terminals;

wherein the COF structure further comprises:

at least one groove disposed over the output terminals of the metal layer, wherein when the COF structure is assembled with the glass substrate of the array substrate, an anisotropic conductive film is provided between the output terminals of the COF structure and a plurality of terminals of the glass substrate, and the output terminals are electrically connected to the terminals of the glass substrate by heating and pressing the plastic substrate over the output terminals.

In one embodiment of the present invention, the plastic substrate is a plastic substrate of polyimide.

In one embodiment of the present invention, the depth of the at least one groove is equal to or smaller than the thickness of the plastic substrate.

In one embodiment of the present invention, the width of the at least one groove is equal to or smaller than the thickness of the plastic substrate.

In one embodiment of the present invention, the at least one groove is linear.

In one embodiment of the present invention, the at least one groove is sawtooth-like.

In one embodiment of the present invention, the at least one groove is waved.

To achieve the above object, the present invention further provides a COF structure for a liquid crystal panel, which is disposed on an edge of a glass substrate of an array substrate of a liquid crystal panel, the COF structure comprises:

a plastic substrate;

a metal layer having two ends provided with a plurality of input terminals and a plurality of output terminals, respectively;

an adhesive layer disposed between the plastic substrate and the metal layer to bond the plastic substrate with the metal layer;

a driver chip disposed on the outer surface of the plastic substrate, and being electrically connected with the metal layer; and
an insulating protection layer disposed on the outer surface of the metal layer, and exposing the input terminals and the output terminals;

wherein the COF structure further comprises:

a plurality of through holes disposed over the output terminals of the metal layer, wherein when the COF structure is assembled with the glass substrate of the array substrate, an anisotropic conductive film is provided between the output terminals of the COF structure and a plurality of terminals of the glass substrate, and the output terminals are electrically connected to the terminals of the glass substrate by heating and pressing the plastic substrate over the output terminals.

In one embodiment of the present invention, the plastic substrate is a plastic substrate of polyimide.

In one embodiment of the present invention, the depth of the through holes are equal to the thickness of the plastic substrate.

In one embodiment of the present invention, the diameter of the through holes are equal to or smaller than the thickness of the plastic substrate.

The present invention provides a COF structure for a liquid crystal panel, which is disposed on an edge of a glass substrate of an array substrate of a liquid crystal panel. The COF structure comprises a plastic substrate, a metal layer, an adhesive layer, a driver chip and an insulating protection layer. The COF structure further comprises at least one groove, and the groove is disposed on the plastic substrate over the output terminals of the metal layer. The at least one groove of the present invention can prevent from deformation and damage of the COF structure when the COF structure is assembled with the glass substrate of the array substrate, and it can reduce the brightness difference of the glass substrate in the thermally pressed regions.

### DESCRIPTION OF THE DRAWINGS

FIG. 1 is a top view of a traditional a chip on film (COF) structure assembled on a liquid crystal panel;

FIG. 2 is a cross-sectional side view of the traditional COF structure assembled on the liquid crystal panel;

FIG. 3 is a top view of a COF structure assembled on a liquid crystal panel according to a first preferred embodiment of the present invention;

FIG. 4 is a cross-sectional side view of the COF structure assembled on the liquid crystal panel according to the first preferred embodiment of the present invention;

FIG. 5 is a top view of a COF structure assembled on a liquid crystal panel according to a second preferred embodiment of the present invention;

FIG. 6 is a top view of a COF structure assembled on a liquid crystal panel according to a third preferred embodiment of the present invention; and

FIG. 7 is a top view of a COF structure assembled on a liquid crystal panel according to a fourth preferred embodiment of the present invention.

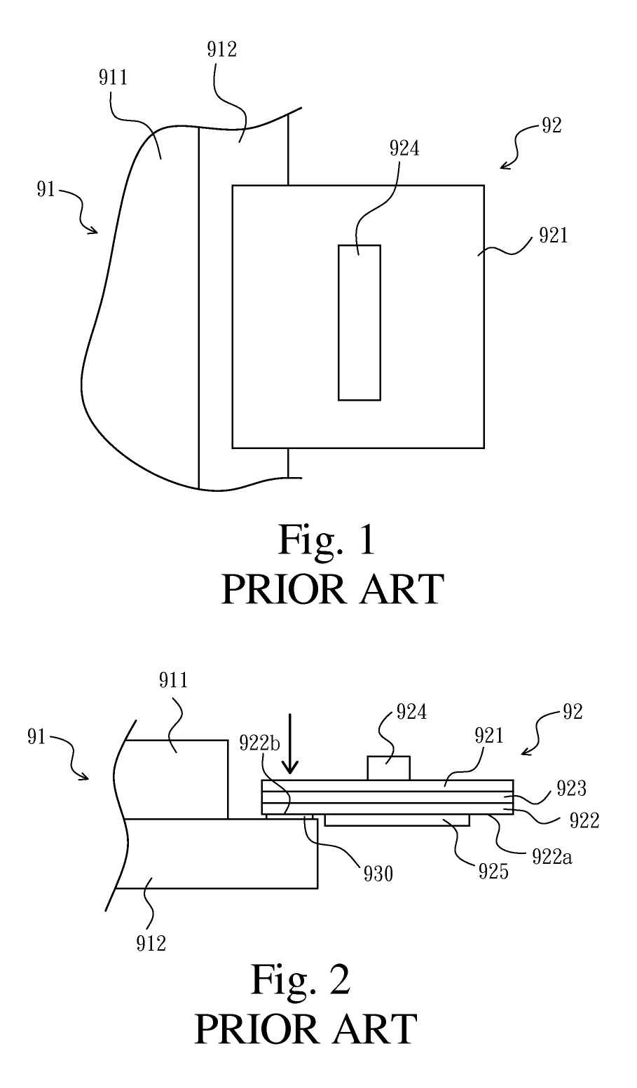

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto.

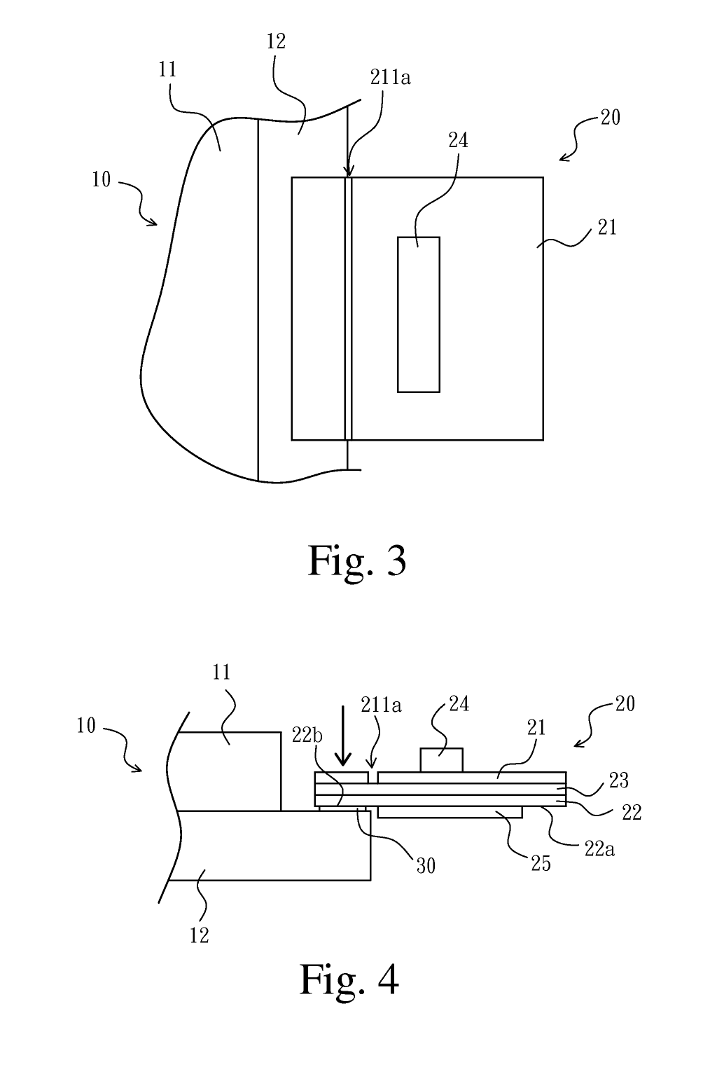

Referring now to FIGS. 3 and 4, a top view of a chip on film (COF) structure assembled on a liquid crystal panel according to a first preferred embodiment of the present invention is illustrated in FIG. 3, and a cross-sectional side view of the COF structure assembled on the liquid crystal panel according to the first preferred embodiment of the present invention is illustrated in FIG. 4. As shown in FIGS. 3 and 4, a liquid crystal panel 10 has a color filter substrate 11 and a glass substrate 12 of an array substrate, and an edge of the glass substrate 12 is provided with a COF structure 20. The COF structure 20 comprises a plastic substrate 21, a metal layer 22, an adhesive layer 23, a driver chip 24 and an insulating protection layer 25. The plastic substrate 21 is a plastic substrate with flexibility, such as polyimide (PI); the metal layer 22 is such as a copper (Cu) metal layer, and two ends of the metal layer 22 is provided with a plurality of input terminals 22a and a plurality of output terminals 22b, respectively; the adhesive layer 23 is disposed between the plastic substrate 21 and the metal layer 22, and the adhesive layer 23 bonds the plastic substrate 21 with the metal layer 22; the driver chip 24 is disposed on the outer surface of the plastic substrate 21, and the driver chip 24 is electrically connected with the metal layer 22 (not shown); the insulating protection layer 25, such as green solder mask, is disposed on the outer surface of the metal layer 22, and the Insulating protection layer 25 exposes the input terminals 22a and the output terminals 22b.

In addition, the COF structure 20 Further comprises at least one groove 211a, as shown in FIG. 4, and the groove 211a is linearly disposed on the plastic substrate 21 over the output terminals 22b of the metal layer 22. Therefore, when the COF structure 20 is assembled with the glass substrate 12 of the array substrate, an anisotropic conductive film (ACF) 30 is provided between the output terminals 22b of the COF structure 20 and a plurality of terminals (not shown) of the glass substrate 12, and the output terminals 22b are electrically connected with the terminals of the glass substrate 12 by heating and pressing (referring to the direction of the arrow as shown in FIG. 4) the plastic substrate 21 over the output terminals 22b, so as to finish the assembly of the COF structure 20 and the liquid crystal panel 10.

Because the COF structure 20 is disposed on the glass substrate 12 by thermally pressing, when the applied pressure is excessive, the groove 211a can cause that the material of the plastic substrate 21 is pushed toward the space formed by the groove 211a, so as to prevent from that the deformation and damage of the glass substrate 12 during assembly, and to reduce the brightness difference of the glass substrate 12 in the thermally pressed regions. Preferably, the depth of the at least one groove 211 a is equal to or smaller than the thickness of the plastic substrate 21; and the width of the at least one groove 211a is equal to or smaller than the thickness of the plastic substrate 21.

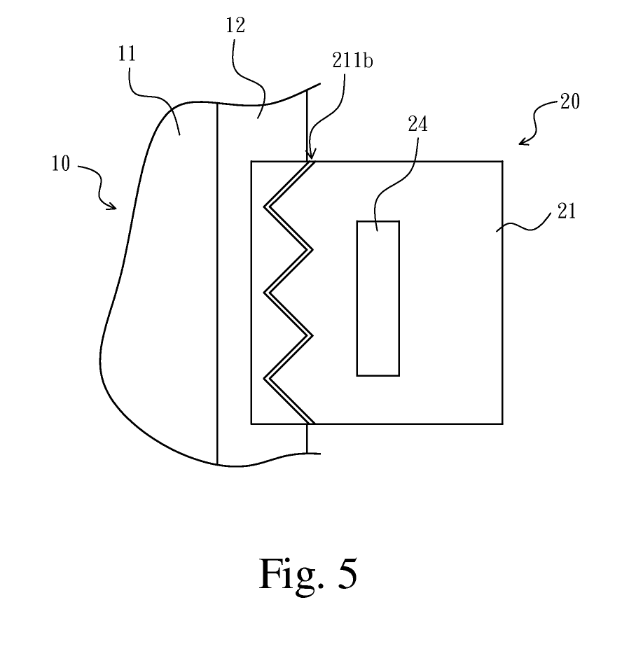

Referring now to FIG. 5, a top view of a COF structure assembled on a liquid crystal panel according to a second preferred embodiment of the present invention is illustrated in FIG. 5. The COF structure 20 of the embodiment is similar to the COF structure 20 in the first embodiment, so as to use similar terms and numerals of the foregoing embodiment, the difference of this embodiment is that: the at least one groove 211b is sawtooth-like. The sawtooth-like groove 211b can averagely disperse the force applied onto the plastic substrate 21 along the X-axis and the Y-axis in the horizontal direction.

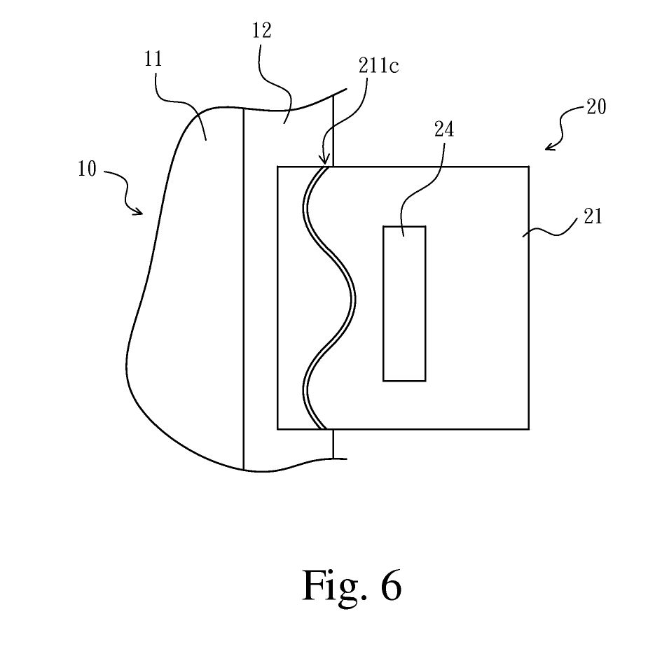

Referring now to FIG. 6, a top view of a COF structure assembled on a liquid crystal panel according to a third preferred embodiment of the present invention is illustrated in FIG. 6. The COF structure 20 of the embodiment is similar to the COF structures 20 in the first and second embodiments, so as to use similar terms and numerals of the foregoing embodiments, the difference of this embodiment is that: the at least one groove 211c of this embodiment is waved. The wave-like groove 211c also can averagely disperse the force applied the plastic substrate 21 along the X-axis and the Y-axis in the horizontal direction.

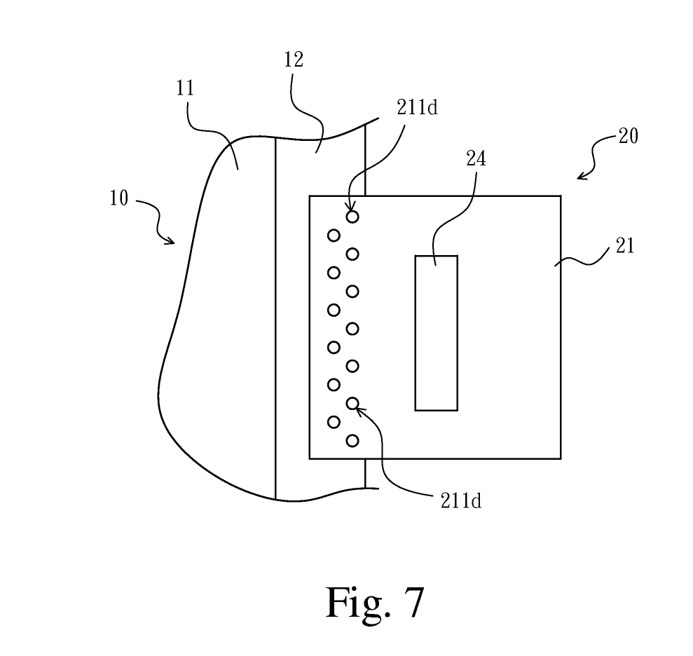

Referring now to FIG. 7, a top view of a COF structure assembled on a liquid crystal panel according to a fourth preferred embodiment of the present invention is illustrated in FIG. 7. The COF structure 20 of the embodiment is similar to the COF structures 20 of the foregoing embodiments, so as to use similar terms and numerals of the foregoing embodiments, the difference of this embodiment is that: the COF structure 20 further comprises a plurality of through holes 211d to replace the grooves (211a, 211b, 211c) in other embodiments, and the through holes 211d are disposed on the plastic substrate 21 over the output terminals 22b of the metal layer 22.

Preferably, the depth of the through holes 211d is equal to the thickness of the plastic substrate 21; and the diameter of the through holes 211d is equal to or smaller than the thickness of the plastic substrate 21, so as to provide an effect that is similar to the grooves (211a, 211b, 211c) of other embodiments.

As described above, in comparison with the traditional COF structure which is thermally pressed to a glass substrate of an array substrate and thus the glass will become deformed and warped in the thermally pressed regions, to cause and the gap between the upper glass and lower glass substrates of the array substrate has a variation between the thermally pressed regions and non-thermally pressed regions and thus cause the transmittance of light has a variation between different regions, the COF structure 20 of the present invention has the design of forming the at least one groove (211a,211b,211c) or the through holes 211d on the plastic substrate over the output terminals 22b of the metal layer 22, so as to prevent from deformation and damage of the COF structure when the COF structure 20 is assembled with the glass substrate 12 of the array substrate by thermally pressing, and to reduce the brightness difference of the glass substrate 12 in the thermally pressed regions.

The present invention has been described with a preferred embodiment thereof and it is understood that many changes and modifications to the described embodiment can be carried out without departing from the scope and the spirit of the invention that is intended to be limited only by the appended claims.

1. A chip-on-film (COF) structure for a liquid crystal panel, which is disposed on an edge of a glass substrate of an array substrate of a liquid crystal panel, the COF structure comprising:
a plastic substrate being a plastic substrate of polyimide;
a metal layer having two ends provided with a plurality of input terminals and a plurality of output terminals, respectively;
an adhesive layer disposed between the plastic substrate and the metal layer to bond the plastic substrate with the metal layer;
a driver chip disposed on the outer surface of the plastic substrate, and being electrically connected with the metal layer; and
an insulating protection layer disposed on the outer surface of the metal layer, and exposing the input terminals and the output terminals;
wherein the COF structure is characterized in that: the COF structure further comprises:
at least one sawtooth-like groove disposed over the output terminals of the metal layer, wherein when the COF structure is assembled with the glass substrate of the array substrate, an anisotropic conductive film is provided between the output terminals of the COF structure and a plurality of terminals of the glass substrate, and the output terminals are electrically connected to the terminals of the glass substrate by heating and pressing the plastic substrate over the output terminals.

2. The COF structure according to claim 1, characterized in that: the depth of the at least one groove is equal to or smaller than the thickness of the plastic substrate.

3. The COF structure according to claim 1, characterized in that: the width of the at least one groove is equal to or smaller than the thickness of the plastic substrate.

4. A chip-on-film (COF) structure for a liquid crystal panel, which is disposed on an edge of a glass substrate of an array substrate of a liquid crystal panel, the COF structure comprising:
a plastic substrate;
a metal layer having two ends provided with a plurality of input terminals and a plurality of output terminals, respectively;
an adhesive layer disposed between the plastic substrate and the metal layer to bond the plastic substrate with the metal layer;
a driver chip disposed on the outer surface of the plastic substrate, and being electrically connected with the metal layer; and
an insulating protection layer disposed on the outer surface of the metal layer, and exposing the input terminals and the output terminals;
wherein the COF structure is characterized in that: the COF structure further comprises:
at least one groove disposed over the output terminals of the metal layer, wherein when the COF structure is assembled with the glass substrate of the array substrate, an anisotropic conductive film is provided between the output terminals of the COF structure and a plurality of terminals of the glass substrate, and the output terminals are electrically connected to the terminals of the glass substrate by heating and pressing the plastic substrate over the output terminals.

5. The COF structure according to claim 4, characterized in that: the plastic substrate is a plastic substrate of polyimide.

6. The COF structure according to claim 4, characterized in that: the depth of the at least one groove is equal to or smaller than the thickness of the plastic substrate.

7. The COF structure according to claim 4, characterized in that: the width of the at least one groove is equal to or smaller than the thickness of the plastic substrate.

8. The COF structure according to claim 4, characterized in that: the at least one groove is linear.

9. The COF structure according to claim 4, characterized in that: the at least one groove is sawtooth-like.

10. The COF structure according to claim 4, characterized in that: the at least one groove is waved.

11. A chip-on-film (COF) structure for a liquid crystal panel, which is disposed on an edge of a glass substrate of an array substrate of a liquid crystal panel, the COF structure comprising:
a plastic substrate;
a metal layer having two ends provided with a plurality of input terminals and a plurality of output terminals, respectively;
an adhesive layer disposed between the plastic substrate and the metal layer to bond the plastic substrate with the metal layer;
a driver chip disposed on the outer surface of the plastic substrate, and being electrically connected with the metal layer; and
an insulating protection layer disposed on the outer surface of the metal layer, and exposing the input terminals and the output terminals;
wherein the COF structure is characterized in that: the COF structure further comprises:
a plurality of through holes disposed over the output terminals of the metal layer, wherein when the COF structure is assembled with the glass substrate of the array substrate, an anisotropic conductive film is provided between the output terminals of the COF structure and a plurality of terminals of the glass substrate, and the output terminals are electrically connected to the terminals of the glass substrate by heating and pressing the plastic substrate over the output terminals.

12. The COF structure according to claim 11, characterized in that: the plastic substrate is a plastic substrate of polyimide.

13. The COF structure according to claim 11, characterized in that: the depth of the through holes are equal to the thickness of the plastic substrate.

14. The COF structure according to claim 11, characterized in that: the diameter of the through holes are equal to or smaller than the thickness of the plastic substrate.
